(19) United States
(12) Patent Application Publication
(10) Pub. No.: US 2026/0271318 A1
(43) Pub. Date: Sep. 10, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Taichi FUKUDA, Yokohama Kanagawa (JP); Takahiro KATO, Nonoichi Ishikawa (JP); Ryohei GEJO, Kawasaki Kanagawa (JP); Tatsunori SAKANO, Shinagawa Tokyo (JP); Yusuke KOBAYASHI, Yokohama Kanagawa (JP); Takato YAMAMOTO, Kawasaki Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/443,125

(22) Filed: Jan. 8, 2026

(30) Foreign Application Priority Data
Mar. 5, 2025 (JP) 2025-034758

(51) Int. Cl. H10D 12/00; H10D 62/10; H10D 62/60; H10D 64/27

(52) U.S. Cl. CPC H10D 12/481; H10D 12/415; H10D 62/103; H10D 62/126; H10D 62/60; H10D 64/518

(57) ABSTRACT

According to one embodiment, a semiconductor device includes a collector electrode, an emitter electrode, a first gate electrode, a first gate wiring member, a semiconductor member, a first insulating member, and a second insulating member. The semiconductor member includes first to fifth semiconductor regions. The fifth semiconductor region includes a first semiconductor portion. At least a part of the first insulating member is provided between the first gate electrode and the semiconductor member. The second insulating member includes a first insulating region. The first insulating region is provided between the first gate wiring member and the emitter electrode in a second direction intersecting with the first direction. The fourth semiconductor region includes a first overlapping region overlapping the first insulating region in the first direction. The first semiconductor portion does not overlap the first insulating region in the first direction.

### CROSS-REFERENCE TO RELATED APPLICATIONS

This application is based upon and claims the benefit of priority from Japanese Patent Application No. 2025-034758, filed on Mar. 5, 2025; the entire contents of which are incorporated herein by reference.

### FIELD

Embodiments described herein relate generally to a semiconductor device.

### BACKGROUND

For example, a stable operation is desirable for semiconductor devices.

### BRIEF DESCRIPTION OF THE DRAWINGS

FIG. 1 is a schematic transparent perspective view illustrating a semiconductor device according to a first embodiment;

FIGS. 2A and 2B are schematic cross-sectional views illustrating the semiconductor device according to the first embodiment;

FIG. 3 is a schematic cross-sectional view illustrating the semiconductor device according to the first embodiment;

FIG. 4 is a schematic plan view illustrating the semiconductor device according to the first embodiment;

FIG. 5 is a schematic cross-sectional view illustrating a semiconductor device according to a second embodiment;

FIG. 6 is a schematic cross-sectional view illustrating the semiconductor device according to the second embodiment;

FIG. 7 is a schematic plan view illustrating the semiconductor device according to the second embodiment; and

FIG. 8 is a schematic plan view illustrating a semiconductor device according to a third embodiment.

### DETAILED DESCRIPTION

According to one embodiment, a semiconductor device includes a collector electrode, an emitter electrode, a first gate electrode, a first gate wiring member, a semiconductor member, a first insulating member, and a second insulating member. The first gate wiring member is electrically connected to the first gate electrode. The semiconductor member is provided between the collector electrode and the emitter electrode in a first direction from the collector electrode to the emitter electrode. The semiconductor member includes a first semiconductor region of a first conductivity type, a second semiconductor region of a second conductivity type provided between the first semiconductor region and the emitter electrode, a third semiconductor region of the first conductivity type provided between the second semiconductor region and the emitter electrode and electrically connected to the emitter electrode, a fourth semiconductor region of the second conductivity type provided between the first semiconductor region and the collector electrode, and a fifth semiconductor region of the first conductivity type provided between the first semiconductor region and the collector electrode. The fifth semiconductor region includes a first semiconductor portion. At least a part of the first insulating member is provided between the first gate electrode and the semiconductor member. The second insulating member includes a first insulating region. The first insulating region is provided between the first gate wiring member and the emitter electrode in a second direction intersecting with the first direction. The fourth semiconductor region includes a first overlapping region overlapping the first insulating region in the first direction. The first semiconductor portion does not overlap the first insulating region in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

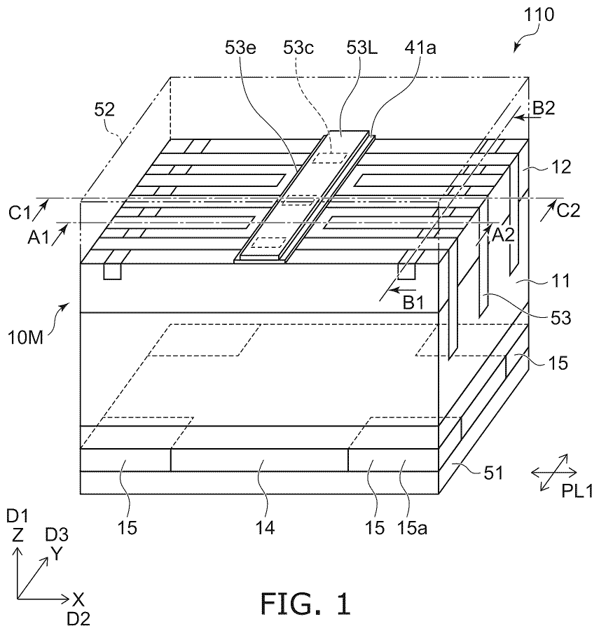

FIG. 1 is a schematic transparent perspective view illustrating a semiconductor device according to a first embodiment.

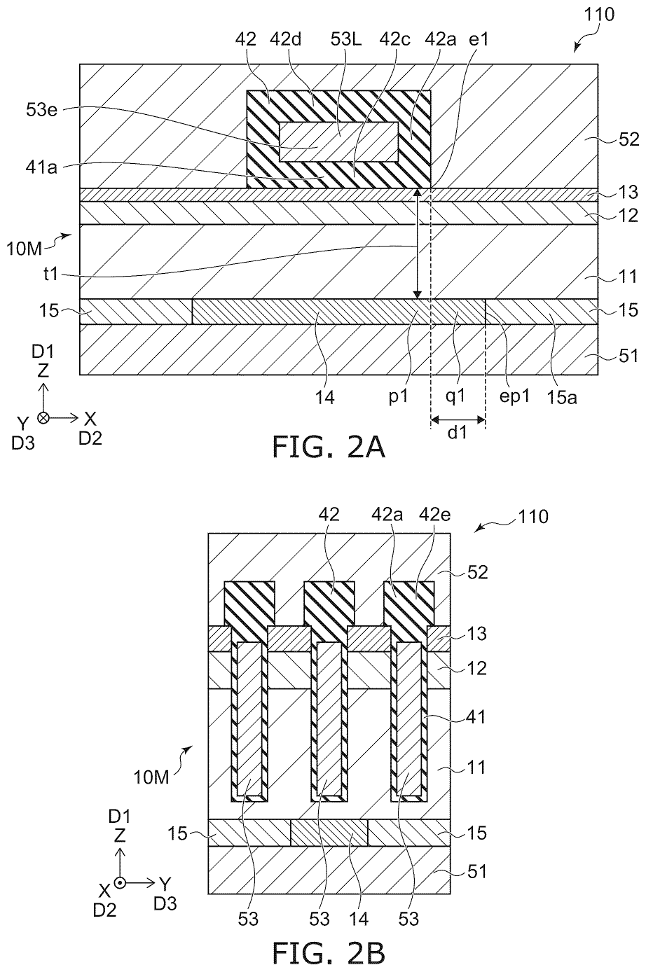

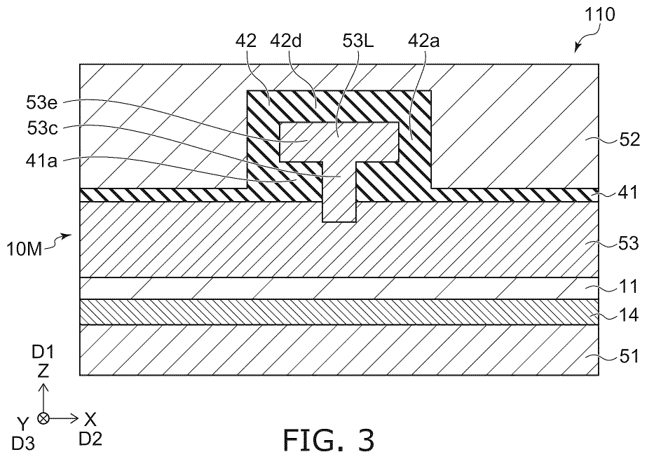

FIGS. 2A and 2B and FIG. 3 are schematic cross-sectional views illustrating the semiconductor device according to the first embodiment.

FIG. 2A is a cross-sectional view taken along line A1-A2 of FIG. 1. FIG. 2B is a cross-sectional view taken along line B1-B2 of FIG. 1. FIG. 3 is a cross-sectional view taken along line C1-C2 of FIG. 1.

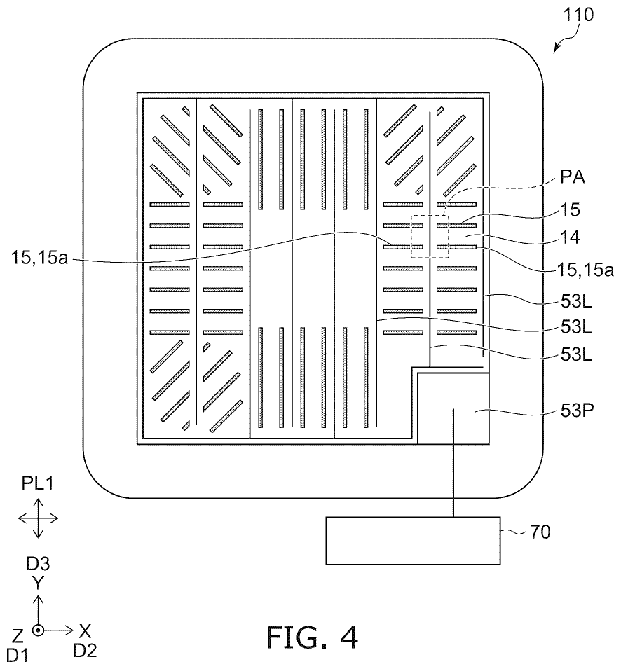

FIG. 4 is a schematic plan view illustrating the semiconductor device according to the first embodiment.

FIG. 1, FIGS. 2A and 2B, and FIG. 3 illustrate a part PA in FIG. 4.

As shown in FIG. 1, FIGS. 2A and 2B, and FIG. 3, a semiconductor device 110 according to the embodiment includes a collector electrode 51, an emitter electrode 52, a first gate electrode 53, a semiconductor member 10M, a first insulating member 41, and a second insulating member 42.

A first gate wiring member 53L is electrically connected to the first gate electrode 53. In this example, the first gate wiring member 53L is electrically connected to the first gate electrode 53 by a first connection portion 53c. The semiconductor member 10M is provided between the collector electrode 51 and the emitter electrode 52 in a first direction D1 from the collector electrode 51 to the emitter electrode 52.

The first direction D1 is defined as a Z-axis direction. One direction perpendicular to the Z-axis direction is defined as an X-axis direction. A direction perpendicular to the Z-axis direction and the X-axis direction is defined as a Y-axis direction.

The first gate electrode 53 extends, for example, along the X-axis direction. At least a part of the first gate wiring member 53L intersects with the direction in which the first gate electrode 53 extends. In this example, a part of the first gate wiring member 53L extends along the Y-axis direction.

The semiconductor member 10M includes a first semiconductor region 11 of a first conductivity type, a second semiconductor region 12 of a second conductivity type, a third semiconductor region 13 of the first conductivity type, a fourth semiconductor region 14 of the second conductivity type, and a fifth semiconductor region 15 of the first conductivity type. The first conductivity type is one of the n-type and the p-type. The second conductivity type is the other of the n-type and the p-type. It is assumed below that the first conductivity type is the n-type and the second conductivity type is the p-type.

As shown in FIGS. 2A and 2B, the second semiconductor region 12 is provided between the first semiconductor region 11 and the emitter electrode 52. The third semiconductor region 13 is provided between the second semiconductor region 12 and the emitter electrode 52. The second semiconductor region 12 is electrically connected to the emitter electrode 52.

The fourth semiconductor region 14 is provided between the first semiconductor region 11 and the collector electrode 51. For example, the fourth semiconductor region 14 is in contact with a part of the first semiconductor region 11 and a part of the collector electrode 51.

The fifth semiconductor region 15 is provided between the first semiconductor region 11 and the collector electrode 51. For example, the fifth semiconductor region 15 is in contact with another part of the first semiconductor region 11 and another part of the collector electrode 51.

For example, the impurity concentration (fifth impurity concentration) of the first conductivity type in the fifth semiconductor region 15 may be higher than the impurity concentration (first impurity concentration) of the first conductivity type in the first semiconductor region 11. The fifth semiconductor region 15 is, for example, an n⁺-region. The first semiconductor region 11 is, for example, an n-region or an n⁻-region. The fifth semiconductor region 15 includes a first semiconductor portion 15a. The fifth semiconductor region 15 may include a plurality of the first semiconductor portions 15a.

The impurity concentration (third impurity concentration) of the first conductivity type in the third semiconductor region 13 is higher than the impurity concentration (first impurity concentration) of the first conductivity type in the first semiconductor region 11. The third semiconductor region 13 is, for example, an n⁺-region.

The second semiconductor region 12 and the fourth semiconductor region 14 are, for example, p⁺-regions. The second semiconductor region 12 is, for example, a p⁺-base layer.

At least a part of the first insulating member 41 is provided between the first gate electrode 53 and the semiconductor member 10M. The first insulating member 41 electrically insulates the first gate electrode 53 and the semiconductor member 10M from each other. The first insulating member 41 faces a part of the first semiconductor region 11, the second semiconductor region 12, the third semiconductor region 13, and the first gate electrode 53 in a direction intersecting with the first direction D1. The first insulating member 41 may be in contact with the first semiconductor region 11, the second semiconductor region 12, the third semiconductor region 13, and the first gate electrode 53.

In this example, the first gate electrode 53 is between a part of the semiconductor member 10M and another part of the semiconductor member 10M in a direction intersecting with the first direction D1. A part of the first semiconductor region 11 is between the collector electrode 51 and the first gate electrode 53 in the first direction D1.

As shown in FIG. 2A, the second insulating member 42 includes a first insulating region 42a. The first insulating region 42a is provided between the first gate wiring member 53L and the emitter electrode 52 in a second direction D2. The second direction D2 intersects with the first direction D1. The second direction D2 may be, for example, the X-axis direction. In this example, the first insulating region 42a is provided between the second semiconductor region 12 and the emitter electrode 52 in the first direction D1. The first insulating region 42a may be provided between the third semiconductor region 13 and the emitter electrode 52 in the first direction D1. As shown in FIG. 2A, at least a part of the second insulating member 42 is provided between the first gate wiring member 53L and the emitter electrode 52. The second insulating member 42 electrically insulates the first gate wiring member 53L and the emitter electrode 52 from each other. The second insulating member 42 may be provided between the first gate wiring member 53L and the semiconductor member 10M. The second insulating member 42 electrically insulates the first gate wiring member 53L and the semiconductor member 10M from each other.

For example, a direction from the first gate wiring member 53L to the first insulating region 42a is along the second direction D2. At least a part of the first gate wiring member 53L extends along a third direction D3. The third direction D3 intersects with a plane that includes the first direction D1 and the second direction D2. The position of the first gate wiring member 53L in the first direction D1 is different from the position of the semiconductor member 10M in the first direction D1.

The fourth semiconductor region 14 includes a first overlapping region p1 overlapping the first insulating region 42a in the first direction D1. The first semiconductor portion 15a of the fifth semiconductor region 15 does not overlap the first insulating region 42a in the first direction D1. For example, the first semiconductor portion 15a is separated from the first insulating region 42a when projected onto the X-Y plane.

As shown in FIG. 2A, for example, a direction from the first overlapping region p1 to the first semiconductor portion 15a intersects with the first direction D1. In this example, the direction from the first overlapping region p1 to the first semiconductor portion 15a is along the second direction D2.

The fourth semiconductor region 14 includes a first intermediate region q1. The first intermediate region q1 is between the first overlapping region p1 and the first semiconductor portion 15a in the second direction D2 intersecting with the first direction D1.

The semiconductor device 110 is, for example, an RC-IGBT (Reverse Conductive Insulated Gate Bipolar Transistor).

As described above, in the embodiment, the first semiconductor portion 15a of the fifth semiconductor region 15 does not overlap the first insulating region 42a in the first direction D1. As shown in FIG. 4, a plurality of the first gate wiring members 53L may be provided. For example, the position of the first semiconductor portion 15a in the second direction D2 may be between the position of one of the plurality of first gate wiring members 53L in the second direction D2 and the position of another one of the plurality of first gate wiring members 53L in the second direction D2. The one of the plurality of first gate wiring members 53L is next to the other one of the plurality of first gate wiring members 53L. Accordingly, for example, in the forward operation, accumulation of holes in a region overlapping the first insulating region 42a can be suppressed. In the recovery operation, the holes can be efficiently discharged toward the emitter electrode 52. For example, breakage is suppressed. For example, instability in the parasitic diode operation can be suppressed. A high breakdown voltage is obtained. According to the embodiment, a semiconductor device enabling a stable operation can be provided.

In the embodiment, for example, an n⁺-region of the back face is not provided immediately below a region in which the emitter and the base are insulated from each other by the interlayer insulating film. Accordingly, a passage for the holes in the recovery operation can be obtained, and the holes can flow into the emitter electrode 52.

As shown in FIG. 2A, the first semiconductor portion 15a includes a first semiconductor portion end ep1 facing the first intermediate region q1 in the second direction D2. The first insulating region 42a includes a first end e1 in the second direction D2. The distance, along the second direction D2, between the position (first end position) of the first end e1 in the second direction D2 and the position (first semiconductor portion end position) of the first semiconductor portion end ep1 in the second direction D2 is defined as a first distance d1. The thickness, along the first direction D1, between the fourth semiconductor region 14 and the first insulating region 42a is defined as a first thickness t1. In the embodiment, for example, the first distance d1 may be 0.01 times or more the first thickness t1. Holes can be stably discharged. The first distance d1 may be 2 times or less the first thickness t1. A stable IGBT operation is obtained.

In one example, the first distance d1 may be 300 μm or more.

For example, the impurity concentration of the second conductivity type in the second semiconductor region 12 is defined as a second impurity concentration. In one example, the second impurity concentration is not less than 1×10¹⁶ cm⁻³ and not more than 1×10¹⁷ cm⁻³. At this time, the first distance d1 may be 100 μm or more.

In another example, the second impurity concentration is not less than 1×10¹⁷ cm⁻³ and not more than 1×10¹⁸ cm⁻³. At this time, the first distance d1 may be 200 μm or more.

In one example, the breakdown voltage of the semiconductor device 110 is 1 kV or more. At this time, the first distance d1 may be 50 μm or more.

In one example, the breakdown voltage is 4 kV or more. At this time, the first distance d1 may be 100 μm or more.

In one example, the breakdown voltage is 5 kV or more. At this time, the first distance d1 may be 200 μm or more.

The area of the fifth semiconductor region 15 in a first plane PL1 intersecting with the first direction D1 is defined as a first area S1. The area of the first semiconductor region 11 in the first plane PL1 is defined as a second area S2. The ratio (S1/S2) of the first area S1 to the second area S2 may be 0.3% or more. A stable IGBT operation and a stable diode operation are obtained.

As shown in FIG. 2A, the second insulating member 42 may include a third insulating region 42c and a fourth insulating region 42d. In the first direction D1, the third insulating region 42c is between the semiconductor member 10M and the first gate wiring member 53L. In the first direction D1, the fourth insulating region 42d is between the first gate wiring member 53L and the emitter electrode 52. As shown in FIG. 2B, the second insulating member 42 may include a fifth insulating region 42e. The fifth insulating region 42e is between the first gate electrode 53 and the emitter electrode 52.

As shown in FIG. 4, the first gate wiring member 53L is electrically connected to a gate pad 53P. A controller 70 may be electrically connected to the gate pad 53P. A gate signal is supplied from the controller 70 to the gate pad 53P. The first gate wiring member 53L may extend along any direction that is along the first plane PL1.

At least a part of the first gate wiring member 53L is in the cell region. A part of the first gate wiring member 53L may be provided in the termination region.

For example, the first gate wiring member 53L extends along the third direction D3 (for example, the Y-axis direction).

For example, the first gate electrode 53 extends along the second direction D2 (for example, the X-axis direction). As shown in FIG. 3, the first gate wiring member 53L overlaps the first gate electrode 53 in the first direction D1.

As shown in FIG. 3, the first gate wiring member 53L includes a first extending portion 53e and a first connection portion 53c. The first extending portion 53e extends along the third direction D3 (for example, the Y-axis direction). In a portion in which the first gate wiring member 53L and the first gate electrode 53 intersect with each other, the first connection portion 53c is between the first gate electrode 53 and the first extending portion 53e. In the intersecting portion, a part of the first semiconductor region 11 is provided between the collector electrode 51 and the first gate electrode 53. In the intersecting portion, the first semiconductor region 11 is in contact with the first insulating member 41.

As shown in FIG. 2A, the first insulating member 41 includes a first insulating portion 41a. At least a part of the first insulating portion 41a is between the semiconductor member 10M and the first extending portion 53e in the first direction D1. An end portion of the first insulating portion 41a in the second direction D2 may be continuous with the first insulating region 42a. The end portion of the first insulating portion 41a in the second direction D2 may be provided between the semiconductor member 10M and the first insulating region 42a in the first direction D1.

One of a plurality of the first gate electrodes 53 may intersect with a plurality of the first gate wiring members 53L. For example, one of the plurality of first gate electrodes 53 may intersect with three or more first gate wiring members 53L. One of the plurality of first gate electrodes 53 is connected to each of the three or more first gate wiring members 53L by the first connection portion 53c.

### Second Embodiment

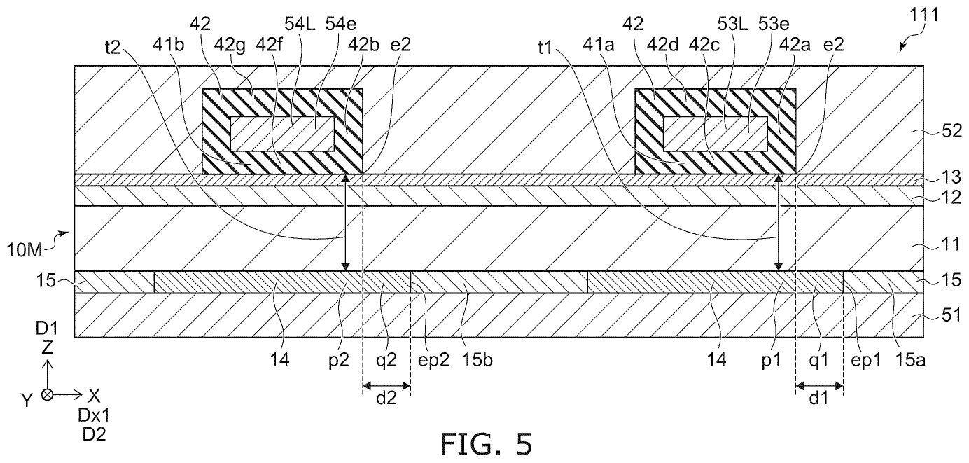

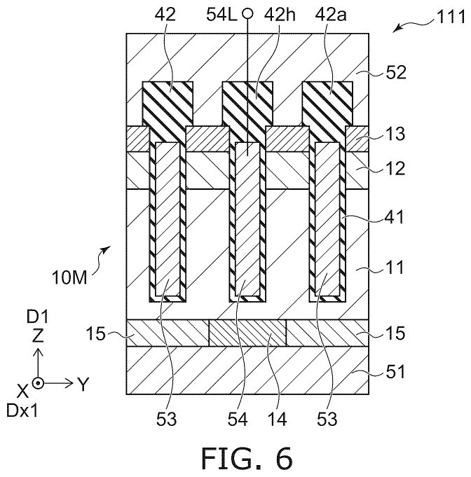

FIG. 5 and FIG. 6 are schematic cross-sectional views illustrating a semiconductor device according to a second embodiment.

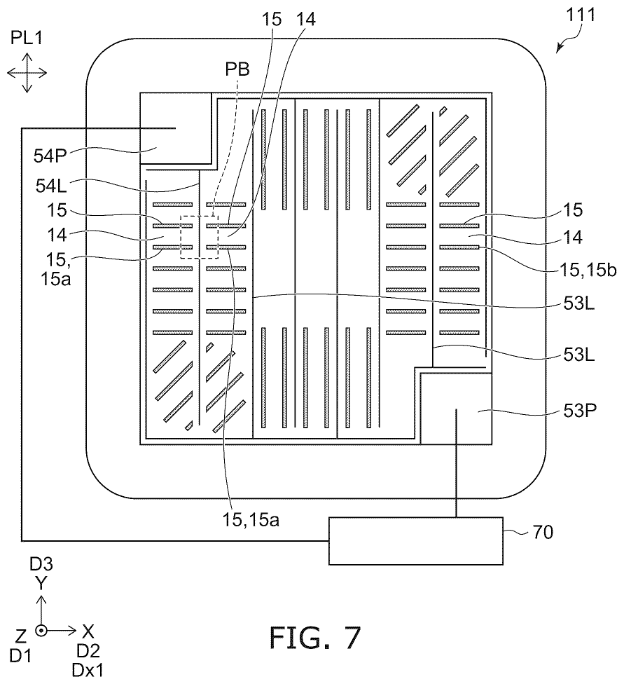

FIG. 7 is a schematic plan view illustrating the semiconductor device according to the second embodiment.

FIG. 5 and FIG. 6 illustrate a part PB in FIG. 7.

As shown in FIG. 5 and FIG. 6, a semiconductor device 111 according to the embodiment includes a second gate electrode 54 and a second gate wiring member 54L. The configuration of the semiconductor device 111 is otherwise similar to the configuration of the semiconductor device 110.

The second gate wiring member 54L is electrically connected to the second gate electrode 54. The second gate electrode 54 is electrically insulated from the first gate electrode 53. The second gate wiring member 54L is electrically insulated from the first gate wiring member 53L. The second gate electrode 54 and the first gate electrode 53 may operate as control electrodes independent of each other. The semiconductor device 111 is, for example, an RC-IGBT having a double gate structure.

As shown in FIG. 5, the fifth semiconductor region 15 further includes a second semiconductor portion 15b. As shown in FIG. 6, another part of the first insulating member 41 is provided between the second gate electrode 54 and the semiconductor member 10M.

As shown in FIG. 5, the second insulating member 42 further includes a second insulating region 42b. The second insulating region 42b is provided between the second gate wiring member 54L and the emitter electrode 52 in a first intersecting direction Dx1 intersecting with the first direction D1. The second direction D2 may be, for example, the X-axis direction. In this example, the second insulating region 42b is provided between the second semiconductor region 12 and the emitter electrode 52 in the first direction D1. In this example, the second insulating region 42b is between the third semiconductor region 13 and the emitter electrode 52 in the first direction D1. The first intersecting direction Dx1 may be along the second direction D2.

A direction from the second gate wiring member 54L to the second insulating region 42b intersects with the first direction D1. In this example, the direction from the second gate wiring member 54L to the second insulating region 42b is along the first intersecting direction Dx1 intersecting with the first direction D1. The first intersecting direction Dx1 may be the X-axis direction.

The fourth semiconductor region 14 includes a second overlapping region p2 overlapping the second insulating region 42b in the first direction D1. The second semiconductor portion 15b does not overlap the second insulating region 42b in the first direction D1.

For example, a direction from the second overlapping region p2 to the second semiconductor portion 15b intersects with the first direction D1. In this example, the direction from the second overlapping region p2 to the second semiconductor portion 15b is along the first intersecting direction Dx1. The fourth semiconductor region 14 includes a second intermediate region q2. The second intermediate region q2 is between the second overlapping region p2 and the second semiconductor portion 15b in the first intersecting direction Dx1 intersecting with the first direction D1.

As shown in FIG. 7, a plurality of the first gate wiring members 53L and a plurality of the second gate wiring members 54L may be provided. For example, the plurality of first gate wiring members 53L are arranged along the second direction D2. For example, the plurality of second gate wiring members 54L are arranged along the second direction D2. The position of one of the fifth semiconductor regions 15 in the second direction D2 is between the position of one of the plurality of second gate wiring members 54L in the second direction D2 and the position of one of the plurality of first gate wiring members 53L in the second direction D2. The one of the plurality of second gate wiring members 54L is closest to the one of the plurality of first gate wiring members 53L, among the plurality of second gate wiring members 54L. The one of the plurality of first gate wiring members 53L is closest to the one of the plurality of second gate wiring members 54L, among the plurality of first gate wiring members 53L.

The structure of the second gate electrode 54 may be similar to the structure of the first gate electrode 53. The structure of the second gate wiring member 54L may be similar to the structure of the first gate wiring member 53L.

In the semiconductor device 111, for example, in the forward operation, accumulation of holes in a region overlapping the second insulating region 42b can be suppressed. In the recovery operation, the holes can be efficiently discharged toward the emitter electrode 52.

In the semiconductor device 111, different signals may be supplied to the first gate wiring member 53L and the second gate wiring member 54L. For example, a first signal is supplied to the first gate wiring member 53L. A second signal is supplied to the second gate wiring member 54L. The second signal may have at least any of a second off timing different from a first off timing of the first signal and a second on timing different from an on timing of the first signal. These signals may be supplied from the controller 70.

As shown in FIG. 7, the first gate wiring member 53L is electrically connected to the gate pad 53P. The second gate wiring member 54L is electrically connected to a control gate pad 54P. The above-described signals may be supplied to these pads from the controller 70. The first gate wiring member 53L may extend along any direction that is along the first plane PL1. The second gate wiring member 54L may extend along any direction along the first plane PL1.

As shown in FIG. 5, the second semiconductor portion 15b includes a second semiconductor portion end ep2 facing the second intermediate region q2 in the first intersecting direction Dx1. The second insulating region 42b includes a second end e2 in the first intersecting direction Dx1. The distance, along the first intersecting direction Dx1, between the position (second end position) of the second end e2 in the first intersecting direction Dx1 and the position (second semiconductor portion end position) of the second semiconductor portion end ep2 in the first intersecting direction Dx1 is defined as a second distance d2. The thickness, along the first direction D1, between the fourth semiconductor region 14 and the second insulating region 42b is defined as a second thickness t2. The second distance d2 may be, for example, 0.01 times or more the second thickness t2. The second distance d2 may be, for example, 2 times or less the second thickness t2.

For example, the second distance d2 may be 300 μm or more. In the embodiment, the first distance d1 may be substantially the same as the second distance d2.

As shown in FIG. 5, the second insulating member 42 may include a sixth insulating region 42f and a seventh insulating region 42g. The sixth insulating region 42f is between the semiconductor member 10M and the second gate wiring member 54L. The seventh insulating region 42g is between the second gate wiring member 54L and the emitter electrode 52.

As shown in FIG. 6, the second insulating member 42 may include an eighth insulating region 42h. The eighth insulating region 42h is between the second gate electrode 54 and the emitter electrode 52.

As shown in FIG. 7, at least a part of the second gate wiring member 54L is in the cell region. A part of the second gate wiring member 54L may be provided in the termination region.

As shown in FIG. 5, the second gate wiring member 54L includes a second extending portion 54e. The second extending portion 54e extends along the third direction D3 (for example, the Y-axis direction). The second extending portion 54e is electrically connected to the second gate electrode 54 by a connection portion similar to the first connection portion 53c described above. The second gate wiring member 54L intersects with the second gate electrode 54.

As shown in FIG. 5, the first insulating member 41 may include a second insulating portion 41b. At least a part of the second insulating portion 41b is between the semiconductor member 10M and the second extending portion 54e in the first direction D1. An end portion of the second insulating portion 41b in the second direction D2 may be continuous with the second insulating region 42b. The end portion of the second insulating portion 41b in the second direction D2 may be provided between the semiconductor member 10M and the second insulating region 42b in the first direction D1.

### Third Embodiment

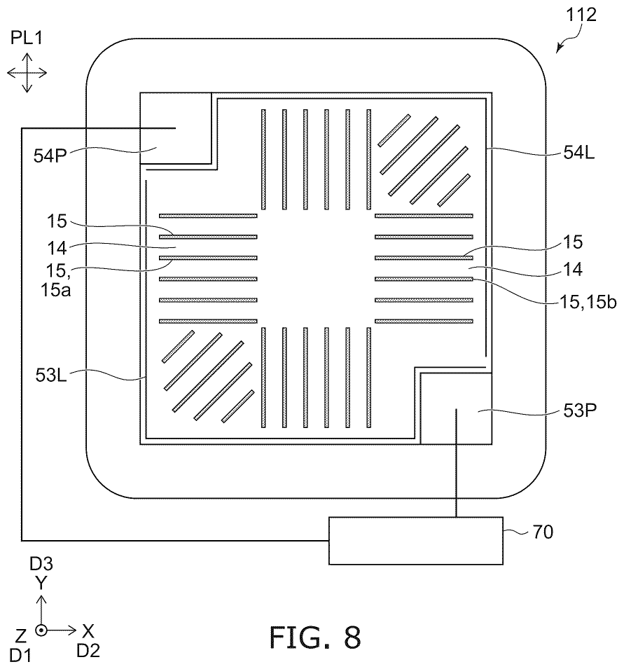

FIG. 8 is a schematic plan view illustrating a semiconductor device according to a third embodiment.

As shown in FIG. 8, a semiconductor device 112 according to the embodiment includes the first gate wiring member 53L and the second gate wiring member 54L. In the semiconductor device 112, these wiring members are provided in the termination region. The configuration of the semiconductor device 112 may be otherwise similar to the configuration of the semiconductor device 111.

As shown in FIG. 8, in the embodiment, at least a part of the first gate wiring member 53L may be provided in the termination region. At least a part of the second gate wiring member 54L may be provided in the termination region.

In the embodiments, the semiconductor member 10M includes, for example, silicon, SiC, or Ge. The semiconductor member 10M may include, for example, a compound semiconductor. The compound semiconductor includes, for example, Ga and N.

At least any of the first insulating member 41 and the second insulating member 42 may include at least one selected from the group consisting of Si, Al, and Hf, and at least one selected from the group consisting of oxygen and nitrogen. At least any of the first insulating member 41 and the second insulating member 42 may include, for example, silicon dioxide.

In the embodiments, information regarding, for example, the shapes of the semiconductor regions is obtained from, for example, an electron microscope image. Information regarding the compositions and the element concentrations is obtained by, for example, EDX (Energy Dispersive X-ray Spectroscopy) or SIMS (Secondary Ion Mass Spectrometry).

The embodiments may include the following technical proposals.

### (Technical Proposal 1)

A semiconductor device comprising:
a collector electrode;
an emitter electrode;
a first gate electrode;
a first gate wiring member electrically connected to the first gate electrode;
a semiconductor member provided between the collector electrode and the emitter electrode in a first direction from the collector electrode to the emitter electrode, the semiconductor member including
   a first semiconductor region of a first conductivity type,
   a second semiconductor region of a second conductivity type provided between the first semiconductor region and the emitter electrode,
   a third semiconductor region of the first conductivity type provided between the second semiconductor region and the emitter electrode and electrically connected to the emitter electrode,
   a fourth semiconductor region of the second conductivity type provided between the first semiconductor region and the collector electrode, and
   a fifth semiconductor region of the first conductivity type provided between the first semiconductor region and the collector electrode, the fifth semiconductor region including a first semiconductor portion;
a first insulating member, at least a part of the first insulating member being provided between the first gate electrode and the semiconductor member; and
a second insulating member including a first insulating region, the first insulating region being provided between the first gate wiring member and the emitter electrode in a second direction intersecting with the first direction,
the fourth semiconductor region including a first overlapping region overlapping the first insulating region in the first direction,
the first semiconductor portion not overlapping the first insulating region in the first direction.

### (Technical Proposal 2)

The semiconductor device according to Technical proposal 1, wherein
a direction from the first overlapping region to the first semiconductor portion intersects with the first direction, and
the fourth semiconductor region further includes a first intermediate region between the first overlapping region and the first semiconductor portion in the second direction.

### (Technical Proposal 3)

The semiconductor device according to Technical proposal 2, wherein
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 0.01 times or more a first thickness, along the first direction, between the fourth semiconductor region and the first insulating region.

### (Technical Proposal 4)

The semiconductor device according to Technical proposal 2, wherein
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 300 μm or more.

### (Technical Proposal 5)

The semiconductor device according to any one of Technical proposals 2 to 4, further comprising:
a second gate electrode; and
a second gate wiring member electrically connected to the second gate electrode,
the second gate electrode being electrically insulated from the first gate electrode,
the second gate wiring member being electrically insulated from the first gate wiring member,
the fifth semiconductor region further including a second semiconductor portion,
another part of the first insulating member being provided between the second gate electrode and the semiconductor member,
the second insulating member further including a second insulating region,
the second insulating region being provided between the second gate wiring member and the emitter electrode in a first intersecting direction intersecting with the first direction,
the fourth semiconductor region including a second overlapping region overlapping the second insulating region in the first direction,
the second semiconductor portion not overlapping the second insulating region in the first direction.

### (Technical Proposal 6)

The semiconductor device according to Technical proposal 5, wherein
a direction from the second overlapping region to the second semiconductor portion intersects with the first direction, and
the fourth semiconductor region further includes a second intermediate region between the second overlapping region and the second semiconductor portion in the first intersecting direction.

### (Technical Proposal 7)

The semiconductor device according to Technical proposal 6, wherein
the second semiconductor portion includes a second semiconductor portion end facing the second intermediate region in the first intersecting direction,
the second insulating region includes a second end in the first intersecting direction, and
a second distance, along the first intersecting direction, between a second end position of the second end in the first intersecting direction and a second semiconductor portion end position of the second semiconductor portion end in the first intersecting direction is 0.01 times or more a second thickness, along the first direction, between the fourth semiconductor region and the second insulating region.

### (Technical Proposal 8)

The semiconductor device according to Technical proposal 6, wherein
the second semiconductor portion includes a second semiconductor portion end facing the second intermediate region in the first intersecting direction,
the second insulating region includes a second end in the first intersecting direction, and
a second distance, along the first intersecting direction, between a second end position of the second end in the first intersecting direction and a second semiconductor portion end position of the second semiconductor portion end in the first intersecting direction is 300 μm or more.

### (Technical Proposal 9)

The semiconductor device according to any one of Technical proposals 5 to 8, wherein
a first signal is supplied to the first gate wiring member,
a second signal is supplied to the second gate wiring member, and
the second signal has at least any of a second off timing different from a first off timing of the first signal and a second on timing different from an on timing of the first signal.

### (Technical Proposal 10)

The semiconductor device according to any one of Technical proposals 5 to 9, wherein at least a part of the second gate wiring member is in a cell region.

### (Technical Proposal 11)

The semiconductor device according to any one of Technical proposals 5 to 9, wherein at least a part of the second gate wiring member is in a termination region.

### (Technical Proposal 12)

The semiconductor device according to any one of Technical proposals 1 to 9, wherein at least a part of the first gate wiring member is in a cell region.

### (Technical Proposal 13)

The semiconductor device according to any one of Technical proposals 1 to 9, wherein at least a part of the first gate wiring member is in a termination region.

### (Technical Proposal 14)

The semiconductor device according to Technical proposal 2, wherein
a second impurity concentration of the second conductivity type in the second semiconductor region is not less than 1×10¹⁶ cm⁻³ and not more than 1×10¹⁷ cm⁻³,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 100 μm or more.

### (Technical Proposal 15)

The semiconductor device according to Technical proposal 2, wherein
a second impurity concentration of the second conductivity type in the second semiconductor region is not less than 1×10¹⁷ cm⁻³ and not more than 1×10¹⁸ cm⁻³,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 200 μm or more.

### (Technical Proposal 16)

The semiconductor device according to Technical proposal 2, wherein
a breakdown voltage is 1 kV or more,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 50 μm or more.

### (Technical Proposal 17)

The semiconductor device according to Technical proposal 2, wherein
a breakdown voltage is 4 kV or more,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 100 μm or more.

### (Technical Proposal 18)

The semiconductor device according to Technical proposal 2, wherein
a breakdown voltage is 5 kV or more,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 200 μm or more.

### (Technical Proposal 19)

The semiconductor device according to any one of Technical proposals 1 to 18, wherein a ratio of a first area of the fifth semiconductor region in a first plane intersecting with the first direction to a second area of the first semiconductor region in the first plane is 0.3% or more.

### (Technical Proposal 20)

The semiconductor device according to any one of Technical proposals 1 to 19, wherein the first gate electrode is between a part of the semiconductor member and another part of the semiconductor member in a direction intersecting with the first direction.

According to the embodiments, a semiconductor device enabling a stable operation is provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to examples. However, the embodiments of the invention are not limited to these examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a collector electrode;
an emitter electrode;
a first gate electrode;
a first gate wiring member electrically connected to the first gate electrode;
a semiconductor member provided between the collector electrode and the emitter electrode in a first direction from the collector electrode to the emitter electrode, the semiconductor member including
a first semiconductor region of a first conductivity type,
a second semiconductor region of a second conductivity type provided between the first semiconductor region and the emitter electrode,
a third semiconductor region of the first conductivity type provided between the second semiconductor region and the emitter electrode and electrically connected to the emitter electrode,
a fourth semiconductor region of the second conductivity type provided between the first semiconductor region and the collector electrode, and
a fifth semiconductor region of the first conductivity type provided between the first semiconductor region and the collector electrode, the fifth semiconductor region including a first semiconductor portion;
a first insulating member, at least a part of the first insulating member being provided between the first gate electrode and the semiconductor member; and
a second insulating member including a first insulating region, the first insulating region being provided between the first gate wiring member and the emitter electrode in a second direction intersecting with the first direction,
the fourth semiconductor region including a first overlapping region overlapping the first insulating region in the first direction,
the first semiconductor portion not overlapping the first insulating region in the first direction.

2. The semiconductor device according to claim 1, wherein
a direction from the first overlapping region to the first semiconductor portion intersects with the first direction, and
the fourth semiconductor region further includes a first intermediate region between the first overlapping region and the first semiconductor portion in the second direction.

3. The semiconductor device according to claim 2, wherein
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 0.01 times or more a first thickness, along the first direction, between the fourth semiconductor region and the first insulating region.

4. The semiconductor device according to claim 2, wherein
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 300 μm or more.

5. The semiconductor device according to claim 2, further comprising:
a second gate electrode; and
a second gate wiring member electrically connected to the second gate electrode,
the second gate electrode being electrically insulated from the first gate electrode,
the second gate wiring member being electrically insulated from the first gate wiring member,
the fifth semiconductor region further including a second semiconductor portion,
another part of the first insulating member being provided between the second gate electrode and the semiconductor member,
the second insulating member further including a second insulating region,
the second insulating region being provided between the second gate wiring member and the emitter electrode in a first intersecting direction intersecting with the first direction,
the fourth semiconductor region including a second overlapping region overlapping the second insulating region in the first direction,
the second semiconductor portion not overlapping the second insulating region in the first direction.

6. The semiconductor device according to claim 5, wherein
a direction from the second overlapping region to the second semiconductor portion intersects with the first direction, and
the fourth semiconductor region further includes a second intermediate region between the second overlapping region and the second semiconductor portion in the first intersecting direction.

7. The semiconductor device according to claim 6, wherein
the second semiconductor portion includes a second semiconductor portion end facing the second intermediate region in the first intersecting direction,
the second insulating region includes a second end in the first intersecting direction, and
a second distance, along the first intersecting direction, between a second end position of the second end in the first intersecting direction and a second semiconductor portion end position of the second semiconductor portion end in the first intersecting direction is 0.01 times or more a second thickness, along the first direction, between the fourth semiconductor region and the second insulating region.

8. The semiconductor device according to claim 6, wherein
the second semiconductor portion includes a second semiconductor portion end facing the second intermediate region in the first intersecting direction,
the second insulating region includes a second end in the first intersecting direction, and
a second distance, along the first intersecting direction, between a second end position of the second end in the first intersecting direction and a second semiconductor portion end position of the second semiconductor portion end in the first intersecting direction is 300 μm or more.

9. The semiconductor device according to claim 5, wherein
a first signal is supplied to the first gate wiring member,
a second signal is supplied to the second gate wiring member, and
the second signal has at least any of a second off timing different from a first off timing of the first signal and a second on timing different from an on timing of the first signal.

10. The semiconductor device according to claim 5, wherein at least a part of the second gate wiring member is in a cell region.

11. The semiconductor device according to claim 5, wherein at least a part of the second gate wiring member is in a termination region.

12. The semiconductor device according to claim 1, wherein at least a part of the first gate wiring member is in a cell region.

13. The semiconductor device according to claim 1, wherein at least a part of the first gate wiring member is in a termination region.

14. The semiconductor device according to claim 2, wherein
a second impurity concentration of the second conductivity type in the second semiconductor region is not less than 1×10¹⁶ cm⁻³ and not more than 1×10¹⁷ cm⁻³,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 100 μm or more.

15. The semiconductor device according to claim 2, wherein
a second impurity concentration of the second conductivity type in the second semiconductor region is not less than 1×10¹⁷ cm⁻³ and not more than 1×10¹⁸ cm⁻³,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 200 μm or more.

16. The semiconductor device according to claim 2, wherein
a breakdown voltage is 1 kV or more,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 50 μm or more.

17. The semiconductor device according to claim 2, wherein
a breakdown voltage is 4 kV or more,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 100 μm or more.

18. The semiconductor device according to claim 2, wherein
a breakdown voltage is 5 kV or more,
the first semiconductor portion includes a first semiconductor portion end facing the first intermediate region in the second direction,
the first insulating region includes a first end in the second direction, and
a first distance, along the second direction, between a first end position of the first end in the second direction and a first semiconductor portion end position of the first semiconductor portion end in the second direction is 200 μm or more.

19. The semiconductor device according to claim 1, wherein a ratio of a first area of the fifth semiconductor region in a first plane intersecting with the first direction to a second area of the first semiconductor region in the first plane is 0.3% or more.

20. The semiconductor device according to claim 1, wherein the first gate electrode is between a part of the semiconductor member and another part of the semiconductor member in a direction intersecting with the first direction.
